(19) United States
(12) Patent Application Publication
(10) Pub. No.: US 2026/0261111 A1
(43) Pub. Date: Sep. 3, 2026

(54) A CIRCUIT APPARATUS AND METHOD FOR DETECTION OF OR DETECTION AND PROTECTION AGAINST CIRCUIT ANOMALY

(71) Applicant: ZERO-ERROR SYSTEMS PTE. LTD., Singapore (SG)

(72) Inventors: - Juanda, Singapore (SG); Wei SHU, Singapore (SG); Joseph Sylvester CHANG, Singapore (SG); Kwen Siong CHONG, Singapore (SG); Arunjai MITTAL

(21) Appl. No.: 19/163,840

(22) PCT Filed: Mar. 15, 2024
(86) PCT No.: PCT/IB2024/052551

§ 371 Date: Sep. 9, 2025

(30) Foreign Application Priority Data
Mar. 16, 2023 (SG) 10202300730S

(51) Int. Cl. H02H 1/00; G01R 19/165; H02H 9/00; H02H 9/02

(52) U.S. Cl. CPC H02H 1/0007; G01R 19/16571; H02H 9/005; H02H 9/02

(57) ABSTRACT

An electronic circuit provides a detection of an anomaly in at least an electronic component. The electronic circuit comprises a detector. The detector is configured to sense a current through the electronic component. The detector is also configured to compare the sensed current with an adaptive threshold current. The electronic circuit may also comprise a determination unit.

### BACKGROUND

The following discussion of the background to the invention is intended to facilitate an understanding of the present invention only. It should be appreciated that the discussion is not an acknowledgement or admission that any of the material referred to was published, known or part of the common general knowledge of the person skilled in the art in any jurisdiction as at the priority date of the invention.

It is well established that an anomaly can occur in circuits, including in propriety and Commercial-Off-the-Shelf (COTS) single devices (e.g., a Metal-Oxide-Semiconductor transistor), Integrated Circuits (ICs), System-on-Chip, System-in-Package, etc. (collectively henceforth termed ICs). For example, in space, an SEL or a micro-SEL may occur when a heavy-ion strikes a semiconductor, and on-earth, the current drawn from a battery may be excessively high due to a fault or a current anomaly due to a fault in an IC. As an anomaly may cause damage to the IC, potential fires, etc., there is a need for a circuit apparatus and a method for the detection of or detection and protection against a circuit anomaly.

FIG. 1 depicts a block diagram of a prior-art [https://digitalcommons.usu.edu/cgi/viewcontent.cgi?article=2272&context=smallsat] detection and protection circuit (Overcurrent Protection Circuit 103) against an anomaly—in this case, an SEL—applied to a Target COTS IC 104. This is based on overcurrent protection where it assumes that when an SEL occurs, the current drawn by the Target COTS IC 104 is multiple times higher than its nominal current.

In this prior-art Conventional Approach 10, the Overcurrent Protection Circuit 103 senses the Load Current i 101 of the Target COTS IC 104 via a Current Sensor 105 and compares it with a pre-determined Threshold Current iₜₕ 102. When an SEL occurs, the Overcurrent Protection Circuit 103 detects that the Load Current i 101≥the Threshold Current iₜₕ 102 and subsequently protects the Target COTS IC 104 by disconnecting the power supply via the Power Switch 106 to the Target COTS IC 104.

Although the prior-art Conventional Approach 10 can detect and protect the target COTS IC 104 from major anomaly (e.g., SEL) events, it suffers from several shortcomings. First, the prior-art Conventional Approach 10 may expose the Target COTS IC 104 to excessively high anomaly (e.g., SEL) current for an extended period of time, thereby potentially damaging the Target COTS IC 104. This period is where the SEL current is increasing but still lower than the predetermined Threshold Current iₜₕ 102. This is because the Threshold Current iₜₕ 102 is usually set multiple times higher than normal load current (e.g., 4-5 times) to prevent false trigger. Second, the prior-art Conventional Approach 10 would not be able to detect anomaly (e.g., SEL) events if the anomaly (e.g., SEL) current is lower than the Threshold Current iₜₕ 102 or close to the normal load current, for example in the event of an anomaly whose current is relatively lower (e.g., a micro-SEL). Although this current may be relatively low, it may still result in localized damage where the operating lifetime of the Target COTS IC 104 is likely to be compromised.

FIG. 2 depicts a block diagram of another prior-art [U.S. Pat. No. 10,566,780] detection and protection circuit 11 against an anomaly—in this case, an SEL—applied to a Target COTS IC 114. In this invention, the rate of current change, di/dt 111, is first compared with the pre-determined rate of current change threshold, (di/dt)ₜₕ 112. When di/dt 111, exceeds (di/dt)ₜₕ 112, the Power Switch 116 is turned off to protect the target COTS IC 114 from SEL.

Although this method is theoretically effective to detect SEL and micro-SEL, it is practically difficult to set a pre-determined (di/dt)ₜₕ 112 as different Target COTS ICs may exhibit different behavior of di/dt, 111.

A common feature amongst all prior-art detection and protection circuits and methods is that the threshold parameter (either current threshold or rate of change) is a fixed parameter or a range thereof.

In short, the prior-art conventional approaches are inadequate.

The present invention aims to provide an improved circuit apparatus and a method for the detection of and protection against circuit anomaly (including SEL, micro-SEL, etc.) over the prior-art.

### SUMMARY

In an embodiment, an electronic circuit providing detection of an anomaly in at least an electronic component is disclosed. The electronic circuit comprises a detector configured to sense a current through the electronic component and compare the sensed current with an adaptive threshold current.

In another embodiment, an electronic circuit providing detection of an anomaly in at least an electronic component is disclosed. The electronic circuit comprises a detector and a determination unit. The electronic component is connected to another electronic component. The detector is configured to sense a current through the electronic component and compare the sensed current with an adaptive threshold current or a non-adaptive threshold current. When the sensed current reaches or exceeds the adaptive threshold current or non-adaptive threshold current, the determination unit performs one or a combination of the following: reduces the voltage to the electronic component, reduces or disables the current or the power to the electronic component, reduces the voltage to the another electronic component, reduces or disables the current or the power to the another electronic component, disconnects the another electronic component from the electronic component, or outputs a signal to indicate that an anomaly has occurred.

In yet another embodiment, a method to detect an anomaly in at least an electronic component is disclosed. The method comprises sensing a current through the electronic component and comparing the sensed current against an adaptive threshold current.

### BRIEF DESCRIPTION OF FIGURES

In order that the invention may be fully understood and readily put into practical effect, there shall now be described by way of non-limitative example only exemplary embodiments of the present invention, the description being with reference to the accompanying illustrative drawings.

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1 is a block diagram of a prior-art detection and protection circuit (Overcurrent Protection Circuit 103) against an anomaly, e.g., an SEL.

FIG. 2 is a block diagram of another prior detection and protection Circuit against an anomaly, e.g., an SEL.

FIG. 3 is a block diagram of a generic implementation of an anomaly (e.g., SEL) detection or detection and protection circuit apparatus and method in accordance with a first embodiment of the invention.

FIG. 4 is a block diagram of an anomaly (e.g., SEL) detection or detection and protection circuit apparatus and method in accordance with a second embodiment of the invention.

FIG. 5 is a flow diagram of illustrating an anomaly (e.g., SEL) detection or detection and protection method in accordance with an embodiment of the invention.

FIG. 6 is a block diagram of an anomaly (e.g., SEL) detection or detection and protection circuit apparatus and method in accordance with a third embodiment of the invention.

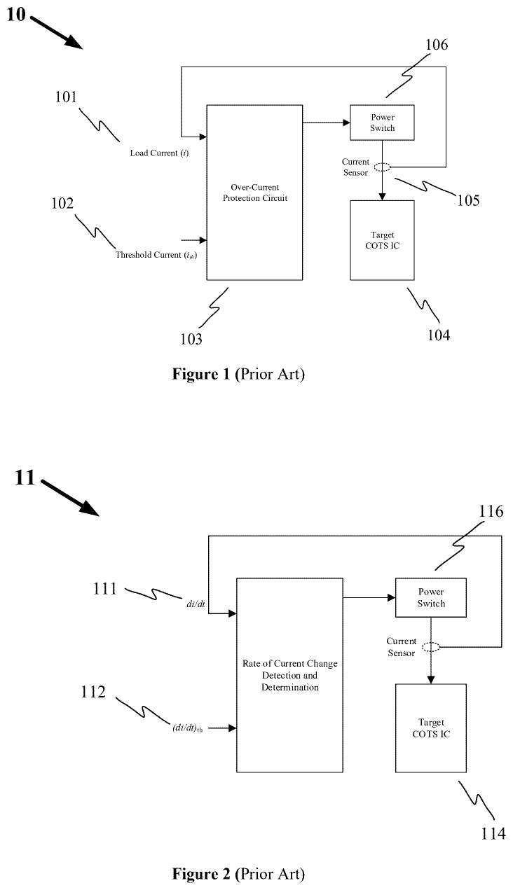

### DETAILED DESCRIPTION

Embodiments of the invention generally relate to a circuit apparatus and a method for the detection of and protection against a circuit anomaly. The circuit anomaly includes that arising from radiation effects (e.g., Single-Event-Latchup (SEL) and micro-SEL) and non-radiation effects (e.g., high current anomaly of a battery).

According to an aspect of the present disclosure, there is provided a circuit apparatus and a method for the detection of or detection of and protection against circuit anomaly, including SEL, micro-SELs, due to other faults such as battery, IC faults, etc. For sake of illustration, the anomaly assumed herein is an SEL (or a micro-SEL) although the anomaly may take other forms, including that arising from non-radiation effects. The circuit apparatus and method comprise one or more of the following:
(a) Readout unit configured to sense load current (i) and apply signal conditioning such as amplification, filtering, scaling, offset, an initial threshold with or without changing values to the initial threshold, rate of change, single-order or higher-order differentiation, single-order or higher-order integration, current profile, variants of the current profile, envelop of the current profile, variants of the envelop of the current profile, etc.
(b) Threshold generation unit configured to provide an absolute threshold current (iₜₕ), and to apply signal processing, e.g., that delineated in (a) above, etc. to the absolute load current (i) to generate an adaptive threshold current (i_{adapt,th}).
(c) Detector(s) configured to compare the absolute load current (i) with an absolute threshold current (iₜₕ), and to compare the absolute load current (i) with the adaptive threshold current (i_{adapt,th}).
(d) Determination unit configured to assert an anomaly (e.g., SEL) flag signal if the absolute load current (i)≥the absolute threshold current (iₜₕ), and/or the absolute load current (i)≥the adaptive threshold current (i_{adapt,th}), and
(e) Recovery unit configured to trigger a power cycling sequence when an anomaly (e.g., SEL) flag signal is asserted to remove the target IC from an anomaly (e.g., SEL) state. The power cycling sequence typically starts with a power shutdown followed by an “off” period before the power is resumed to the target IC.

Thus, embodiments of present invention provide a circuit apparatus and method for anomaly (e.g., SEL) detection and protection that senses an absolute load current (i) and generates threshold currents (iₜₕ and i_{adapt,th}), and detects an anomaly (e.g., SEL) when the absolute load current (i) is equal to or exceeds the absolute threshold current (iₜₕ), and/or the absolute load current (i) is equal to or exceeds the adaptive threshold current (i_{adapt,th}) or a variant thereof, and for protection, triggers a power shut-down to the target IC when an anomaly (e.g., SEL) is detected. Accordingly, embodiments of the invention ensure that rapid anomaly (e.g., SEL) detection and therefore the power to the target IC can be disconnected (or the voltage of the supply to the target IC is reduced) as quickly as possible. Such a system is clearly advantageous over the prior-art which relies solely on detecting anomaly (e.g., SEL) events when the absolute load current is equal to or exceeds an absolute threshold current—i.e., not an adaptive threshold current or a variant thereof.

The advantages of embodiments of the present invention are achieved through comparing the absolute load current (i) with the adaptive threshold current (i_{adapt,th}) (or its variants) to more quickly and accurately detect an anomaly, e.g., SEL and micro-SEL events.

The primary advantages of triggering a shut-down when the absolute load current (i) is equal to or exceeding the adaptive threshold current (i_{adapt,th}) (or its variants) include the ability to detect the anomaly (e.g., both SEL and micro-SELs) events, and a quicker response/detection. The adaptive threshold current (i_{adapt,th}) (or its variants) adapts to the absolute load current (i) at relatively low speed such that even a small abnormal increase in absolute load current (Δi) can be detected. Furthermore, the relatively small difference between the absolute load current (i) and the adaptive threshold current (i_{adapt,th}) (or its variants) allows a shorter detection/response time compared to that using absolute threshold current (iₜₕ).

In some embodiments, the absolute load current (i) may be detected by sensing the voltage (Vₛₑₙₛₑ) across a sense resistor with resistance Rₛₑₙₛₑ where Vₛₑₙₛₑ is proportional or in some fashion related to the absolute load current (i)×Rₛₑₙₛₑ. A voltage amplifier may be provided to amplify Vₛₑₙₛₑ above noise level for better signal processing.

In some embodiments, the first detector may comprise a comparator for comparing the absolute load current (i) with an absolute threshold current (iₜₕ).

In some embodiments, the second detector may comprise a second comparator for comparing the absolute load current (i) with the adaptive threshold current (i_{adapt,th}).

In some embodiments, the second detector may comprise a second comparator for comparing an adaptive threshold current (i_{fast-adapt,th}) with another adaptive threshold current at lower rate (i_{slow-adapt,th}).

The anomaly (e.g., SEL) protection module may comprise one or more logic gates and may be synchronous or asynchronous. The target IC may be an electronic component including a transistor, a passive electronic component, including a diode, a circuit constructed from discrete electronic components, an integrated circuit, a system-on-chip, an electronic module, or a system-in-package. The target IC may be propriety or COTS. It should be understood that the threshold values will largely be determined by characteristics of the target IC, i.e., its load.

In some embodiments, the target IC may be configured for a space or an on-earth application.

The recovery unit may trigger a power cycling stage to shut-down the target IC (including disconnecting the power or reducing the voltage of the power line to below a certain voltage) and subsequently resume power (or increasing the voltage of the power rail) to the target IC after a pre-determined “off” duration (i.e., a power cycling duration). The pre-determined duration may be calculated to ensure that the anomaly (e.g., SEL) state is completely eradicated. The power cycling time may be determined empirically. In some embodiments, a power cycling duration of several milliseconds will typically be sufficient to remove the unwanted anomaly (e.g., SEL) state.

In accordance with an aspect of the invention there is provided a circuit apparatus comprising a circuit for the detection of and protection against an anomaly (e.g., an SEL) in accordance with the first aspect of the invention and a target IC.

In accordance with an aspect of the invention there is provided a method of detection of and protection against an anomaly (e.g., an SEL) for a target IC comprising:
(a) Sensing an absolute load current (i);
(b) Generating an absolute threshold current (iₜₕ) and an adaptive threshold current (i_{adapt,th});
(c) Comparing the absolute load current (i) with the absolute threshold current (iₜₕ);
(d) Comparing the absolute load current (i) with the adaptive threshold current (i_{adapt,th});
(e) Asserting an anomaly (e.g., SEL) flag signal if
   the absolute load current (i)≥the absolute threshold current (iₜₕ), and/or the absolute load current (i)≥the adaptive threshold current (i_{adapt,th}); and
(f) Triggering a power cycling sequence when anomaly (e.g., SEL) flag signal is asserted to remove the target IC from anomaly (e.g., SEL) state.

In accordance with another aspect of the invention, the target IC is connected to a preceding IC where when an anomaly is detected the anomaly in the target IC is not removed by power cycling. This is because the preceding connections (e.g., I/O lines of the preceding IC) continue to maintain a high current anomaly in the connections (e.g., I/O lines or input lines) of target IC-despite the no power condition during power cycling. In this another aspect of the invention, this anomaly is resolved by power cycling both the preceding IC and the target IC when an anomaly is detected in the target IC. Note that the preceding IC and the target IC may share or not share the same power rails.

This delineation does not describe an exhaustive list of all aspects of the present invention. It is anticipated that the present invention includes all methods, apparatuses and systems that can be practiced from all appropriate combinations and permutations of the various aspects in this summary, as well as that delineated below. Such combinations and permutations may have specific advantages not specially described in this summary.

Throughout this document, unless otherwise indicated to the contrary, the terms “comprising”, “consisting of”, “having” and the like, are to be construed as non-exhaustive, or in other words, as meaning “including, but not limited to.”Furthermore, throughout the specification, unless the context requires otherwise, the word “include” or variations such as “includes” or “including” will be understood to imply the inclusion of a stated integer or group of integers but not the exclusion of any other integer or group of integers.

In accordance with a first embodiment of the present invention there is provided a circuit apparatus and a method for the detection of or detection and protection against circuit anomaly. The circuit anomalies include that arising from radiation effects—an SEL, micro-SEL, etc.—and other circuit anomalies include other non-radiation effects, e.g., high current anomaly of a battery, when a component malfunctions leading to higher current, etc. For sake of illustration, the exemplary anomaly is an SEL or a micro-SEL or both, and the exemplary device where the anomaly may occur and to be protected is a target COTS IC. The target COTS IC may also be propriety and COTS single devices, other ICs, System-on-Chip, System-in-Package, etc.

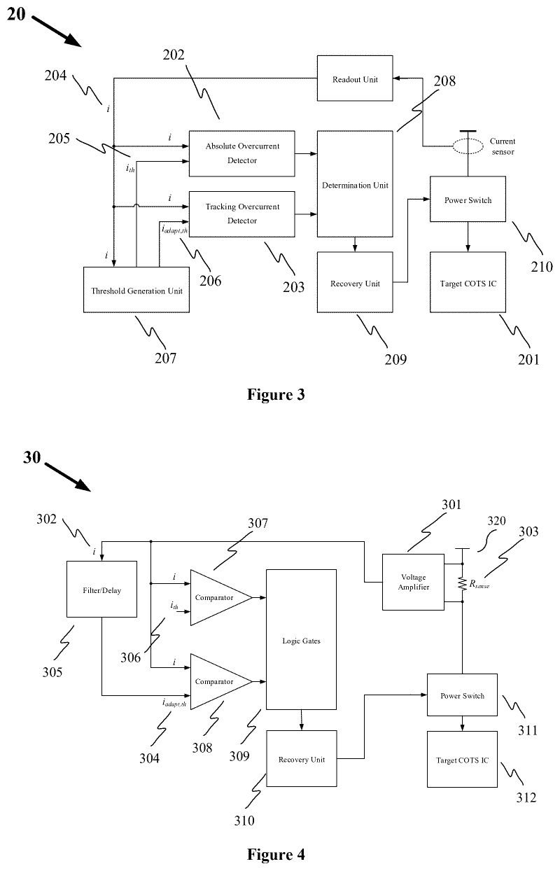

FIG. 3 depicts the circuit apparatus 20 and a method for the detection of or detection and protection against an anomaly (e.g., SEL) for a Target COTS IC 201. The invented circuit apparatus 20 in part comprises a first detector—the Absolute Overcurrent Detector 202—for detecting the absolute overcurrent, and a second detector—the Tracking Overcurrent Detector 203—for detecting the adaptive overcurrent (or variants thereof) of the supply current of the Target COTS IC 201.

Although not shown in FIG. 3, the Absolute Overcurrent Detector 202 may comprise a comparator for comparing the Absolute Load Current i 204 with the Absolute Threshold Current iₜₕ 205; and the Tracking Overcurrent Detector 203 may comprise a comparator for comparing the Absolute Load Current i 204 with the Adaptive Threshold Current i_{adapt,th} 206 (or variants thereof).

The Threshold Generation Unit 207 provides the Absolute Threshold Current iₜₕ 205 and the Adaptive Threshold Current i_{adapt,th} 206 to the Absolute Overcurrent Detector 202 and Tracking Overcurrent Detector 203, respectively. In this embodiment, the Absolute Threshold Current iₜₕ 205 is pre-programmed into the Threshold Generation Unit 207, and the Adaptive Threshold Current i_{adapt,th} 206 is derived from the Absolute Load Current i 204.

Alternatively (not shown in FIG. 3), the Tracking Overcurrent Detector 203 may also comprise a second comparator for comparing the Adaptive Threshold Current i_{fastadapt,th} with another Adaptive Threshold Current at lower rate i_{slow-adapt,th}, which are generated by the Threshold Generation Unit 207.

The output signals from each of the Absolute Overcurrent Detector 202 and Tracking Overcurrent Detector 203 are input to the Determination Unit 208. The Determination Unit 208 is configured to assert an anomaly (e.g., SEL) flag signal if the Absolute Load Current i 204 is equal to or exceeds the Absolute Threshold Current iₜₕ 205 and/or if the Absolute Load Current i 204 is equal to or exceeds the Adaptive Threshold Current i_{adapt,th} 206. When the anomaly (e.g., SEL) flag signal has been asserted, the Recovery Unit 209 is configured to initiate a power cycling sequence, i.e., shut down the power to the Target COTS IC 201 via the Power Switch 210, and to subsequently resume power to the Target COTS IC 201 (by reconnecting Power Switch 210) after a pre-determined duration. The pre-determined duration is established so as to provide sufficient time to remove the anomaly (e.g., SEL) state from a target IC 201.

The variants of the Adaptive Threshold Current i_{adapt,th} 206 for the detection of the anomaly includes one or a combination of the following based on or resembling an adaptive parameter: an initial threshold with or without changing values to the initial threshold, filtering, rate of change, single-order or higher-order differentiation, single-order or higher-order integration, current profile, variants of the current profile, envelop of the current profile, variants of the envelop of the current profile, etc.

A variation of the first embodiment of the invention is that the two detectors in FIG. 3 sense one or a combination of the following based on or resembling an adaptive or non-adaptive parameter: the current, an initial threshold with or without changing values to the initial threshold, filtering, rate of change, single-order or higher-order differentiation, single-order or higher-order integration, current profile, variants of the current profile, envelop of the current profile, variants of the envelop of the current profile, etc. The detection now involves the two detectors comparing their sensed parameters.

This variation of the first embodiment of the invention is advantageous because there is now extended scope to ascertain differences between normal and anomalous operations, hence a more efficacious and accurate means of detection of an anomaly.

FIG. 4 shows a second embodiment of a circuit apparatus 30 and a method for the detection of and protection against circuit anomaly, in accordance with the present invention. Also, as in the first said embodiment, for sake of illustration, the exemplary anomaly is an SEL and where the anomaly may occur in and to be protected is a target COTS IC 312. This embodiment is also based on the general architecture outlined above in relation to FIG. 3

In FIG. 4, the circuit apparatus 30 in part comprises the Voltage Amplifier 301 to sense the load current through the Resistor Rₛₑₙₛₑ 303 connected to Power Rail 320. The Adaptive Threshold Current i_{adapt,th} 304 (or its variants) is derived from the Absolute Load Current i 302 through the Filter/Delay Block 305 (or other signal processing as delineated earlier). The first detector comprises the First comparator 306 that compares the Absolute Load Current (i) 302 with the Absolute Threshold Current (iₜₕ) 306. The second detector comprises the Second Comparator 308 to compare the Absolute Load Current i 302 with the Adaptive Threshold Current i_{adapt,th} 304.

The Logic Gates Block 313 will assert an SEL flag signal for one or both conditions:
if the Absolute Load Current i 302 is equal to or exceeds the Absolute Threshold Current iₜₕ 306, or
if the Absolute Load Current i 302 is equal to or exceeds the Adaptive Threshold Current i_{adapt,th} 304 (or its variants).

Upon receiving of an anomaly (e.g., SEL) flag signal from the Logic Gates Block 309, the Recovery Unit 310 will power cycle. This involves disabling the Power Switch 311 (or lowering the voltage) to the Target COTS IC 312 and will subsequently resume power (or increasing the voltage) to the Target COTS IC 312 by reconnecting Power Switch 311 after a predetermined duration.

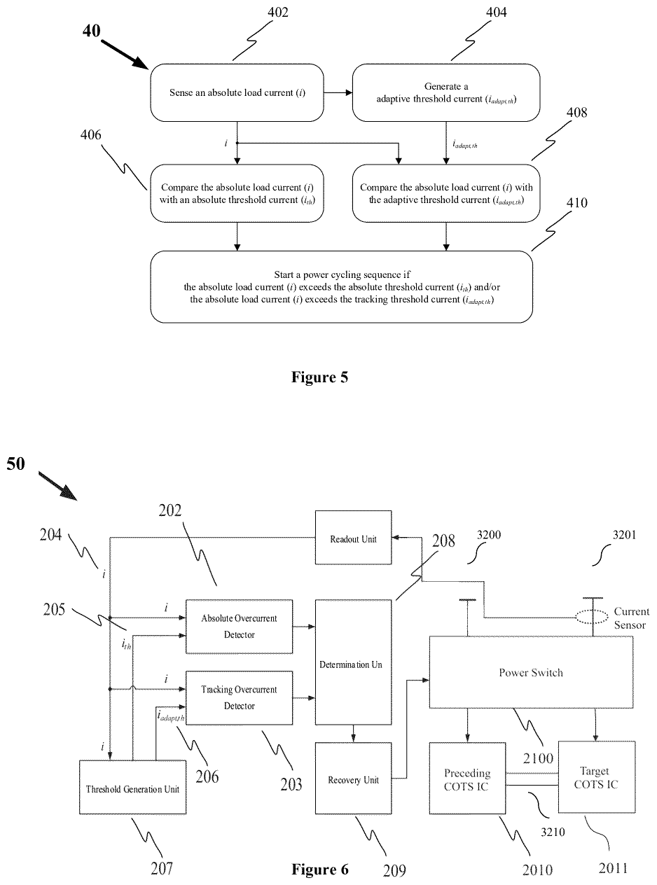

FIG. 5 is the Flow Diagram 40 illustrating the anomaly detection and protection method in accordance with the embodiments of the invention where the anomaly is exemplified by an SEL or a micro-SEL; other anomalies are likewise generally applicable but possibly with some amendments of which are skilled to someone who is skilled in the art. The method comprises the following steps:
Step 1 402: Detect an absolute load current (i) for a target IC;
Step 2 404: Generate an adaptive threshold current (i_{adapt,th}) or its variants;
Step 3 406: Compare the absolute load current (i) with an absolute threshold current (iₜₕ);
Step 4 408: Compare the absolute load current (i) with an adaptive threshold current (i_{adapt,th}) or its variants; and
Step 5 410: Triggering a power cycling sequence to the target IC for one or both of the following:
   if the absolute load current (i)>the absolute threshold current (iₜₕ), or if the absolute load current (i) or a parameter related to the absolute load current (i)>the adaptive threshold current (i_{adapt,th}) or its variants.

Note that also the anomaly has been exemplified by an SEL in a target IC, the invention may also be applied to an energy source (e.g., USB) or an energy storage device (e.g., a battery). For example, if the Target COTS IC 312 in FIG. 4 is a battery, the Power Rail 320 is now the output of the energy source of energy storage device. If the current output of the battery is an anomaly, the invented circuit apparatus and a method 30 will detect the anomaly and if protection is required, it will power cycle the energy source of energy storage device by first disabling the Power Switch 311 and then enabling the same after a predetermined time period or choose to disable Power Switch 311 for all time.

FIG. 6 depicts a block diagram of an anomaly (e.g., SEL) detection or detection and protection circuit apparatus 50 and method in accordance with a third embodiment of the invention. In FIG. 6, there are now two COTS ICs—the Preceding COTS IC 2010 connected to the Target COTS IC 2011. The connections may include the same power rails, i.e., Power Rail 3200 and Power Rail 3201 are coupled, or the Power Rails 3200 and 3201 may be uncoupled, e.g., they have different voltages. The connections also include the I/O Interconnections 3210 between Preceding COTS IC 2010 and Target COTS IC 2011.

This third embodiment of the invention addresses the unresolved problem where an SEL occurs in the Target COTS IC 2011, and when the Target COTS IC 2011 is power cycled, the SEL in Target COTS IC 2011 or sections thereof remains unresolved, i.e., still latched up. The power cycling is affected by the opening and closing of Power Switch 2100 that is connected between Power Rail 3200 and the power pin or terminal of Target COTS IC 2011 (or lowering the voltage to the power pin or terminal)-this is as that delineated earlier. The resolved SEL remains even when the power pin or terminal of Target COTS IC 2011 is disconnected from Power Rail 3201. This is because the I/O pins or terminals of the Preceding COTS IC 2010 connected to the I/O pins or terminals of Target COTS IC 2011 (via I/O Interconnections 3210) continue to provide sufficient power to keep Target COTS IC 2011 or sections thereof in latched-up.

The invented apparatus for detection of or detection and protection apparatus 50 or method resolves this current anomaly (e.g., SEL) problem in Target COTS IC 2011 as follows. When an anomaly in Target COTS IC 2011 is detected and protection is initiated, Target COTS IC 2011 is power cycled by disabling or opening circuit Power Switch 2100 between Power Rail 3201 and the power pin or terminal of Target COTS IC 2011 (or by lowering the voltage to the power pins or terminals). The power to Target COTS IC 2011 is hence disabled. At the same time, Preceding COTS IC 2010 is also power cycled by disabling or opening circuit Power Switch 2100 between Power Rail 3200 and the power pin or terminal of Preceding COTS IC 2010 (or by lowering the voltage to the power pins or terminals). As the power to the Preceding COTS IC 2010 is hence disabled, the I/O pins or terminals of the Preceding COTS IC 2010 is subsequently unable to provide sufficient power to the I/O pins or terminals of Target COTS IC 2011 to keep Target COTS IC 2011 latched-up, i.e., the high current anomaly in Target COTS IC 2011 is resolved. Put simply, the previously unresolved SEL problem is now resolved.

Note that if Power Rail 3200 and Power Rail 3201 are of the same voltage, the same switch in Power Switch 2100 can be used for both the Preceding COTS IC 2010 and the Target COTS IC 2011. If Power Rail 3200 and Power Rail 3201 are of different voltages, two mor more switches in Power Switch 2100 may be required. These variations are known to one skilled in the art.

An advantage of the methods in accordance with the invention is that an anomaly, such as an SEL, can be detected using a combination of absolute overcurrent detection and adaptive overcurrent detection so that protection of the target IC can be implemented when either one of these values reaches or exceeds its respective threshold value.

1. An electronic circuit providing detection of an anomaly in at least an electronic component, and comprising:
a detector configured to
sense a current through the electronic component, and
compare the sensed current with an adaptive threshold current.

2. The electronic circuit according to claim 1 providing protection to the electronic component, and comprising a determination unit, wherein
when the sensed current reaches or exceeds the adaptive threshold current,
the determination unit performs one or a combination of the following:
reduces the voltage to the electronic component,
reduces or disables the current or the power to the electronic component, or
outputs a signal to indicate that an anomaly has occurred.

3. The electronic circuit according to claim 2 wherein
after the sensed current has reached or exceeded the adaptive threshold current, and
after a fixed, variable or adaptive time, the determination unit further performs one or a combination of the following:
increases the voltage to the electronic component,
increases or enables the current or the power to the electronic component, or
outputs a signal to indicate that the anomaly has been resolved.

4. An electronic circuit providing detection of an anomaly in at least an electronic component, and comprising:
a detector; and
a determination unit, wherein
the electronic component is connected to another electronic component,
the detector is configured to
sense a current through the electronic component, and
compare the sensed current with an adaptive threshold current or a non-adaptive threshold current,
and
when the sensed current reaches or exceeds the adaptive threshold current or non-adaptive threshold current, the determination unit performs one or a combination of the following:
reduces the voltage to the electronic component,
reduces or disables the current or the power to the electronic component,
reduces the voltage to the another electronic component,
reduces or disables the current or the power to the another electronic component,
disconnects the another electronic component from the electronic component, or
outputs a signal to indicate that an anomaly has occurred.

5. The electronic circuit according to claim 4 where the electronic component is one or a combination of the following:
a transistor,
a passive electronic component,
a diode,
a circuit constructed from discrete electronic components,
an integrated circuit,
a system-on-chip,
an electronic module, or
a system-in-package.

6. The electronic circuit according to claim 4 where the another electronic component is one or a combination of the following:
a transistor,
a passive electronic component,
a diode,
a circuit constructed from discrete electronic components,
an integrated circuit,
a system-on-chip,
an electronic module, or
a system-in-package.

7. The electronic circuit according to claim 4 where the electronic component and the another electronic component each have a power pin or terminal and a functional pin or terminal, wherein
the connection between the another electronic component and the electronic component is one or a combination of the following:
their power pins are connected, or
their functional pins are connected,
and
the determination unit is configured to be able to disconnect one or a combination of the following:
the connection between the two power pins or terminals,
the connection between the two functional pins or terminals.

8. The electronic circuit according to claim 2 protecting another electronic component, where the another electronic component and the electronic component each having a power pin or terminal wherein,
the power pin or terminal of the another electronic component and the power pin or terminal of the electronic component are coupled, and
when the sensed current reaches or exceeds the adaptive threshold current, the determination unit performs one or a combination of the following to both the electronic component and the another electronic component:
reduces the voltage,
or
reduces or disables the current or the power.

9. The electronic circuit according to claim 1 further comprises a threshold generation unit, wherein
the threshold generation unit provides the adaptive threshold current.

10. The electronic circuit according to claim 1 wherein
the sensed current includes the past and present sensed current values,
the adaptive threshold current is ascertained by signal processing the past and present sensed current values, wherein
the signal processing includes one or a combination of or that resembling the following:
an initial threshold with or without changing values to the initial threshold,
filtering,
rate of change,
single-order or higher-order differentiation,
single-order or higher-order integration,
current profile,
variants of the current profile,
envelop of the current profile, or
variants of the envelop of the current profile.

11. The electronic circuit according to claim 1 wherein the electronic component is an energy storage device or an energy source, wherein
the detector is configured to sense one or a combination of the following:
the output current of the electronic component, or
the output voltage of the electronic component
and
the detector compares one or a combination of the following:
the sensed output current with an adaptive threshold current, or
the sensed output voltage with a fixed or adaptive threshold voltage.

12. The electronic circuit according to claim 1 comprising another detector wherein the detector is configured to
sense transient currents through the electronic component,
and
compare the sensed transient current with either
an adaptive threshold current,
or
an adaptive transient threshold current.
and
the another detector is configured to
sense transient currents at a lower rate through the electronic component,
and
comparing the sensed transient lower-rate current with either
an adaptive threshold current,
or
an adaptive transient threshold current,
or
the sensed transient current.

13. The electronic circuit according to claim 12 wherein the detector and the another detector are further configured to sense one or more of the following which may the same or different values:
an initial threshold with or without changing values to the initial threshold, filtering,
rate of change,
single-order or higher-order differentiation,
single-order or higher-order integration,
current profile,
variants of the current profile,
envelop of the current profile, or
variants of the envelop of the current profile.

14. The electronic circuit according to claim 1 comprising another detector wherein
the detector and the another detector are configured to sense one or more of the following which may the same or different values:
an initial threshold with or without changing values to the initial threshold,
filtering,
rate of change,
single-order or higher-order differentiation,
single-order or higher-order integration,
current profile,
variants of the current profile,
envelop of the current profile,
or
variants of the envelop of the current profile,
and
the detector compares its sensed one or more of the above with that sensed by the another detector.

15. A method to detect an anomaly in at least an electronic component, comprising:
sensing a current through the electronic component,
and
comparing the sensed current against an adaptive threshold current.

16. The method according to claim 15 to further comprising providing protection to the electronic component, wherein
when the sensed current reaches or exceeds the adaptive threshold current,
the protection is derived by one or a combination of the following:
reducing the voltage to the electronic component,
reducing or disabling the current or the power to the electronic component, or
outputting a signal to indicate that an anomaly has occurred.

17. The method according to claim 15 further comprising
after the sensed current has reached or exceeded the adaptive threshold current,
and
after a fixed, variable or adaptive time, performing one or a combination of the following:
increasing the voltage to the electronic component,
increasing or enabling the current or the power to the electronic component, or
outputting a signal to indicate that the anomaly has been resolved.

18. The method according to claim 15 wherein
another electronic component is connected to the electronic component, and the method further comprising
when the sensed current reaches or exceeds the adaptive threshold current,
performing one or a combination of the following:
reducing the voltage to the another electronic component,
reducing or disabling the current or the power to the another electronic component, or
disconnecting the another electronic component from the electronic component.

19. The method according to claim 18 where the electronic component and the another electronic component each have a power pin or terminal and a functional pin or terminal, wherein
the connection between the another electronic component and the electronic component is one or a combination of the following:
their power pins are connected, or
their functional pins are connected,
and the method further comprising
disconnecting, by a determination unit, one or a combination of the following:
the connection between the two power pins or terminals, or
the connection between the two functional pins or terminals.

20. The method according to claim 16 protecting another electronic component, where the another electronic component and the electronic component each having a power pin or terminal wherein,
the power pin or terminal of the another electronic component and the power pin or terminal of the electronic component are coupled, and the method further comprising
when the sensed current reaches or exceeds the adaptive threshold current,
performing one or a combination of the following to both the electronic component and the another electronic component:
reducing the voltage to a power pin or terminal,
or
reducing or disabling the current or the power to a power pin or terminal.
